(19) United States
(12) Patent Application Publication
(10) Pub. No.: US 2009/0117696 A1
(43) Pub. Date: May 7, 2009

(54) Fully logic process compatible non-volatile memory cell with a high coupling ratio and process of making the same

(76) Inventor: Hung-Der Su, Luju Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/318,065

(22) Filed: Dec. 22, 2008

Related U.S. Application Data
(62) Division of application No. 11/771,359, filed on Jun. 29, 2007.

(30) Foreign Application Priority Data
Jul. 4, 2006 (TW) 095124397

(51) Int. Cl. H01L 21/8238; H01L 21/336

(52) U.S. Cl. 438/211; 438/257; 257/E21.634; 257/E21.422

(57) ABSTRACT

A fully logic process compatible non-volatile memory cell has a well on a substrate, a pair of source and drain outside the well, a channel between the source and drain, a control gate in the well, and a floating gate having a first portion above the channel, and a second portion above the well. The control gate includes two regions having opposite conductivity types and a third region between the two regions and under the second portion of the floating gate, and thus eliminates the parasitic depletion capacitor in the coupling path of the cell, thereby improving the coupling ratio.

### RELATED APPLICATIONS

This application is a Divisional patent application of co-pending application Ser. No. 11/771,359, filed on 29 Jun. 2007. The entire disclosure of the prior application, Ser. No. 11/771,359, from which an oath or declaration is supplied, is considered a part of the disclosure of the accompanying Divisional application and is hereby incorporated by reference.

### FIELD OF THE INVENTION

The present invention is related generally to a semiconductor device and, more particularly, to a non-volatile memory.

### BACKGROUND OF THE INVENTION

Non-volatile memories, such as erasable programmable read only memory (EPROM), electrically erasable programmable read only memory (EEPROM), and flash memories, have been widely employed for programmable logics. A typical non-volatile memory cell has the structure 100 as shown in FIG. 1, in which a substrate 110 has a pair of source 120 and drain 130 thereon, a channel 190 between the source 120 and drain 130, a floating gate 150 and a control gate 170 in stack above the channel 190, and oxide layers 140 and 160 interposed between the substrate 110 and the floating gate 150, and between the floating gate 150 and the control gate 170, respectively. When voltages V_{CG} and V_{D} are applied to the control gate 170 and the drain 130, respectively, the control gate voltage V_{CG} is coupled to the floating gate 150 through the oxide layer 160, and then to the substrate 110 through the oxide layer 140, enabling charges to cross over the oxide layer 140 from the channel 190 and enter into the floating gate 150, so that the non-volatile memory cell 100 is programmed. Although the non-volatile memory cell 100 is smaller in size, it must be fabricated by double-polysilicon process, which is complicated and incompatible to logic process such as single-polysilicon process (for example, PMOS or NMOS process), resulting in extra process cost.

To reduce the manufacturing cost, a fully logic process compatible non-volatile memory cell is proposed, see Majid Shalchian, and S. Mojtaba Atarodi, “A logic CMOS Compatible Flash EEPROM for Small Scale Integration”, ICM 2003, Dec. 9-11, Cairo, Egypt, pp. 348-251, as the structure 200 shown in FIG. 2, in which a P-type substrate 210 has a pair of source 260 and drain 262 thereon, a channel 250 between the source 260 and the drain 262, a N-type well. 230, a high-concentration P-type region 264 between the drain 262 and the well 230 as a contact region to prevent the substrate 210 from floating, high concentration N-type regions 270 and 272 in the well 230, a floating gate 220 above the channel .250 and the region 252, an oxide layer 240 interposed between the floating gate 220 and the channel 250 and the region 252, and a field oxide layer 212 to make the non-volatile memory cell 200 to be an independent unit and isolate the drain 262 and the regions 264 and 270. The regions 270, 272 and 252 constitute the control gate 280 of the non-volatile memory cell 200. As shown in FIG. 3, when voltages V_{CG}, V_{D}, V_{S} and V_{B} are applied to the control gate 280, the drain 262, the source 260, and the region 264, respectively, the threshold voltage of inverting N-type to P-type on the surface of the region 252 is lower than the voltage that is coupled from V_{CG} to the floating gate 220, so that the surface of the region 252 is inverted to be a P-type region 310, thereby inducing a parasitic depletion capacitor in the coupling path of from V_{CG} to the floating gate 220, and further causing a drop in the coupling ratio of V_{CG} to the floating gate 220. As a result, for programming the non-volatile memory cell 200, a higher voltage is required to apply to the control gate 280 to enable charges to enter into the floating gate 220 from the channel 250 through the oxide layer 240, and thus the circuit design and the device design of the control circuit become more difficult.

As shown in FIG. 4, a high-concentration N-type region 410 is formed under the floating gate 220 to function as a control gate, in order to eliminate the parasitic depletion capacitor and thus increase the coupling ratio, such that the non-volatile memory cell under lower voltages is programmable and erasable by lower voltage, see Roger Cuppens, Cornelis D. Hartgring, Jan F. Verwey, Herman L. Peek, Frans A. H. Vollebregt, Elisabeth G. M. Devens, and Ingrid A. Sens, “An EEPROM for Microprocessors and Custom Logic”, IEEE Journal of Solid State Circuit, pp. 603-608, Vol. sc-20, No. 2, April 1985, and Jun-Ichi Miyamoto, Jun-Ichi Tsujimoto, Naohiro Matsukawa, Shigeru Morita, Kazuyosi Shinada, Hiroshi Nozawa, and Tetsuya lizuka, “An experimental 5-V-only 256-kbit CMOS EEPROM with a High-Performance Single-Polysilicon Cell”, IEEE Journal of Solid State Circuit, pp. 852-860, Vol. sc-21, No. 5, October 1986. When voltages V_{CG}, V_{D}, V_{S} and V_{B} are applied to the region 410, the drain 262, the source 260, and the region 264, respectively, because the threshold voltage of inverting the surface of the region 410 from N-type to P-type is higher than the voltage that is coupled from V_{CG} to the floating gate 220, no P-type region would be generated on the surface of the region 410, that is, no parasitic depletion capacitor would be induced in the coupling path of from V_{CG} to the floating gate 220, thereby increasing the coupling ratio of the non-volatile memory cell. However, the process of making such structure requires an extra implantation step to produce the region 410, and is not fully logic process compatible, thereby causing higher manufacturing cost.

To improve operational speed and reduce operational voltage, a non-volatile memory cell having a thinner tunneling oxide layer is proposed, see Claudio Contiero, Paola Galbiati, Michele Palmieri, and Lodovica Vecchi, “Characteristics and Applications of a 0.6 μm Bipolar-CMOS-DMOS Technology combining VLSI Non-Volatile Memories”, IEDM 1996, pp. 465-468, as the structure 500 shown in FIG. 5, in which a P-type substrate 510 has high-concentration N-type regions 520, 530, 540, and 542, the region 540 extends into the region 530, a N-type lightly-doped drain 544 and a N-type lightly-doped source 546 are adjoined to the regions 540 and 542, respectively, a channel 552 is between the drain 544 and the source 546, a field oxide layer 560 isolates the regions 520 and 530, an oxide layer 522 is interposed between a floating gate 570 and the region 520, a thinner tunneling oxide layer 580 is interposed between the floating gate 570 and the region 530, and an insulation layer 550 is located between the floating gate 570 and the channel 552. In this structure 500, the region 520 serves as the control gate of the non-volatile memory cell. When voltages V_{CG} and V_{D} are applied to the regions 520 and 540, respectively, because the region 520 is a high-concentration N-type region, no parasitic depletion capacitor, which will cause the coupling ratio to drop, would be generated. In addition, charges pass through the thinner tunneling oxide layer 580 to enter into the floating gate 570, and therefore lower operational voltage is required, and operational speed is improved. However, an extra implantation step, an extra photolithography step, and an extra etching step are required for producing the regions 520 and 530, and the thinner tunneling oxide layer 580, which makes the process not fully logic process compatible, thereby increasing the manufacturing cost.

Therefore, it is desired a fully logic process compatible non-volatile memory cell with a high coupling ratio.

### SUMMARY OF THE INVENTION

An object of the present invention is to provide a fully logic process compatible non-volatile memory cell with a high coupling ratio and a process of making such memory cell.

In an embodiment according to the present invention, a non-volatile memory cell comprises a substrate, a well on the substrate, a pair of source and drain outside the well, a channel between the source and drain, a control gate in the well, and a floating gate extending from above the well to above the channel. The control gate includes two regions having opposite conductivity types, and a third region between these two regions and under the floating gate.

In another embodiment according to the present invention, a non-volatile memory cell comprises a substrate, two wells on the substrate, a control gate in the first well, a pair of source and drain in the second well, a channel between the source and drain, and a floating gate extending from above the first well to above the channel. The control gate includes two regions having opposite conductivity types, and a third region between these two regions and under the floating gate.

According to the present invention, a process of making a non-volatile memory cell comprises a formation of a well on a substrate, a formation of a floating gate extending from above the well to outside the well, and a formation of a pair of source and drain outside the well and two regions having opposite conductivity types in the well such that a channel between the source and drain is under the floating gate and a third region between the first and second regions is under the floating gate.

According to the present invention, a process of making a non-volatile memory cell comprises a formation of two wells on a substrate, a formation of a floating gate extending from above the first well to above the second well, and a formation of a pair of source and drain in the second well and two regions having opposite conductivity types in the first well, such that a third region between the first and second regions is under a first portion of the floating gate and a channel between the source and drain is under a second portion of the floating gate.

With the structure of the control gate, no parasitic depletion capacitor would be induced, and a higher coupling ratio would be achieved. Since the non-volatile memory cell is fabricated by a full logic compatible process, it is suitable for integration into logic products with lower cost.

### BRIEF DESCRIPTION OF THE DRAWINGS

The present invention can be more fully understood by reading the subsequent detailed description and examples with references made to the accompanying drawings; wherein:

FIG. 1 shows the structure of a typical non-volatile memory cell;

FIG. 2 shows the structure of a conventional fully logic process compatible non-volatile memory cell;

FIG. 3 is a diagram when the non-volatile memory cell of FIG. 2 is operated;

FIG. 4 shows the structure of a conventional non-volatile memory cell for eliminating the parasitic depletion capacitor in the coupling path thereof by introducing a high-concentration region;

FIG. 5 shows the structure of a conventional non-volatile memory cell for improving the operational speed and reducing the operational voltage thereof by introducing a thinner tunneling oxide layer;

FIG. 6 shows a first non-volatile memory cell according to the present invention;

FIG. 7 shows a second non-volatile memory cell according to the present invention;

FIG. 8 shows a schematic view for the formation of the well on the substrate for the memory cell shown in FIG. 6;

FIG. 9 shows a schematic view after the formation of a pad oxide layer and a nitride layer stacked on the substrate for the memory cell shown in FIG. 6;

FIG. 10 shows a schematic view after the formation of a hard mask for the memory cell shown in FIG. 6;

FIG. 11 shows a schematic view after the formation of the field oxide layer on the substrate for the memory cell shown in FIG. 6;

FIG. 12 shows a schematic view after the formation of an insulation layer and a conductive layer for the memory cell shown in FIG. 6;

FIG. 13 shows a schematic view after the formation of the floating gate for the memory cell shown in FIG. 6;

FIG. 14 shows a schematic view after the formation of the source and drain for the memory cell shown in FIG. 6;

FIG. 15 shows a schematic view after the formation of the control gate for the memory cell shown in FIG. 6;

FIG. 16 shows a schematic view after the formation of the first well on the substrate for the memory cell shown in FIG. 7;

FIG. 17 shows a schematic view after the formation of the second well on the substrate for the memory cell shown in FIG. 7;

FIG. 18 shows a schematic view after the formation of a pad oxide layer and a nitride layer stacked on the substrate for the memory cell shown in FIG. 7;

FIG. 19 shows a schematic view after the formation of a hard mask for the memory cell shown in FIG. 7;

FIG. 20 shows a schematic view after the formation of the field oxide layer on the substrate for the memory cell shown in FIG. 7;

FIG. 21 shows a schematic view after the formation of an insulation layer and a conductive layer for the memory cell shown in FIG. 7;

FIG. 22 shows a schematic view after the formation of the floating gate for the memory cell shown in FIG. 7;

FIG. 23 shows a schematic view after the formation of the source and drain for the memory cell shown in FIG. 7;

FIG. 24 shows a schematic view after the formation of the control gate for the memory cell shown in FIG. 7;

FIG. 25 illustrates the I-V curves of the conventional non-volatile memory cell shown in FIG. 2 after initialization and being programmed; and

FIG. 26 illustrates the I-V curves of the inventive non-volatile memory cell shown in FIG. 6 after initialization and being programmed.

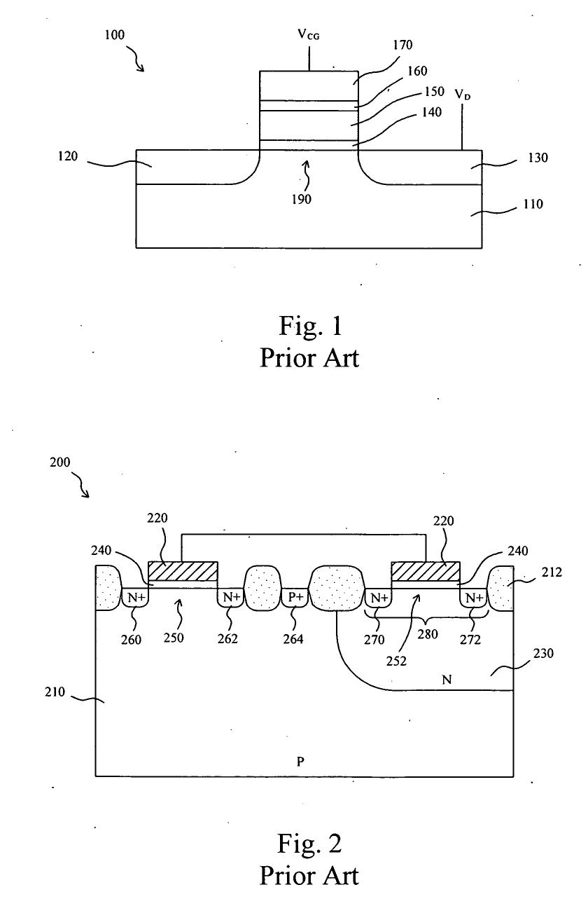

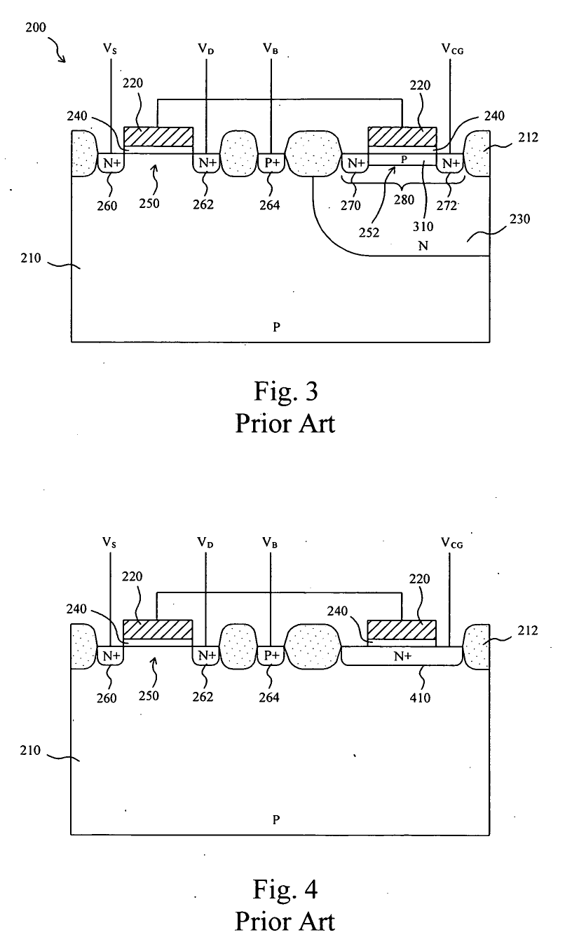

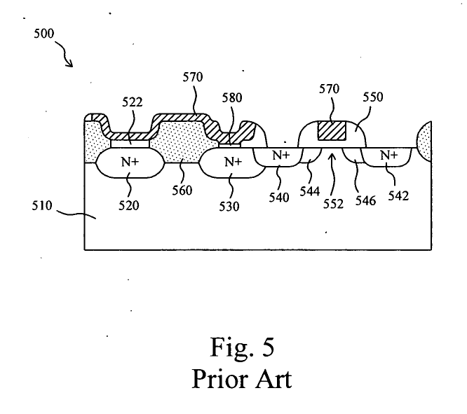

### DETAILED DESCRIPTION OF THE INVENTION

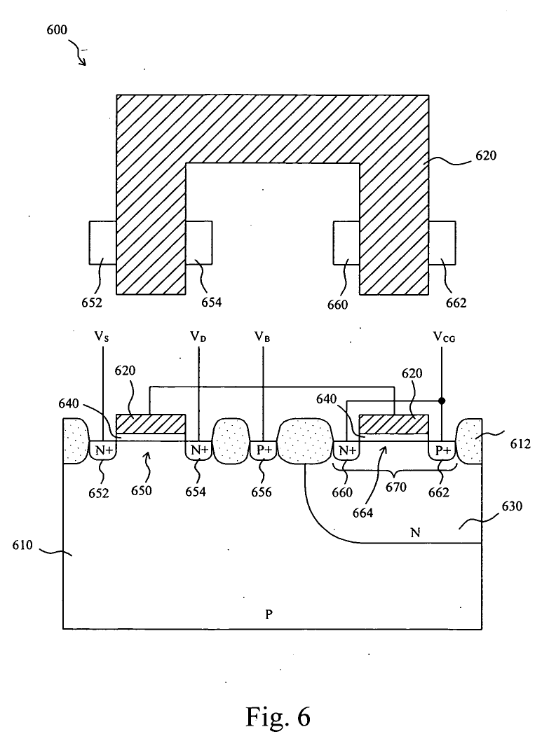

FIG. 6 provides a first embodiment according to the present invention. A non-volatile memory cell 600 comprises a substrate 610 which has a first conductive type, for example P-type, a well 630 which has a second conductive type opposite to the first conductivity type, for example N-type, a pair of source 652 and drain 654 outside the well 630, a channel 650 between the source 652 and drain 654, a control gate 670 in the well 630, a floating gate 620 extending from above the well 630 to above the channel 650, an insulation layer 640 between the floating gate 620 and the channel 650 and the well 630, and a region 656 for serving as a contact region to prevent the substrate 610 from floating, which has the first conductivity type and is on the substrate 610, for example between the drain 654 and the well 630. The control gate 670 includes two regions 660 and 662 having opposite conductivity types, and a region 664 between the regions 660 and 662. In the cross-sectional view, the portions of the floating gate 620 above the channel 650 and the region 664 are separate, but in the top view, they are adjoined. In this embodiment, the insulation layer 640 includes a silicon dioxide, the floating gate 620 includes a polysilicon, and a field oxide layer 612 isolates the non-volatile memory cell 600 to be an independent unit, and the drain 654, region 656, and control gate 670. In other embodiments, a shallow trench isolation (STI) could take the place of the field oxide layer in this embodiment. When voltages V_{CG}, V_{D}, V_{S} and V_{B} are applied to the control gate 670, drain 654, source 652, and region 656, respectively, the voltage coupled from V_{CG} to the floating gate 620 induces the surface of the region 664 to invert from N-type to P-type. Since the induced P-type region is short to the region 662, the voltage at the surface of the region 664 is equal to V_{CG} which is the voltage applied to the control gate 670, and therefore no parasitic depletion capacitor would be induced in the coupling path of from V_{CG} to the floating gate 620, thereby achieving a higher coupling ratio. As a result, for programming the non-volatile memory cell 600, a lower voltage is required for V_{CG} to allow charges to enter into the floating gate 620 from the channel 650 through the insulation layer 640.

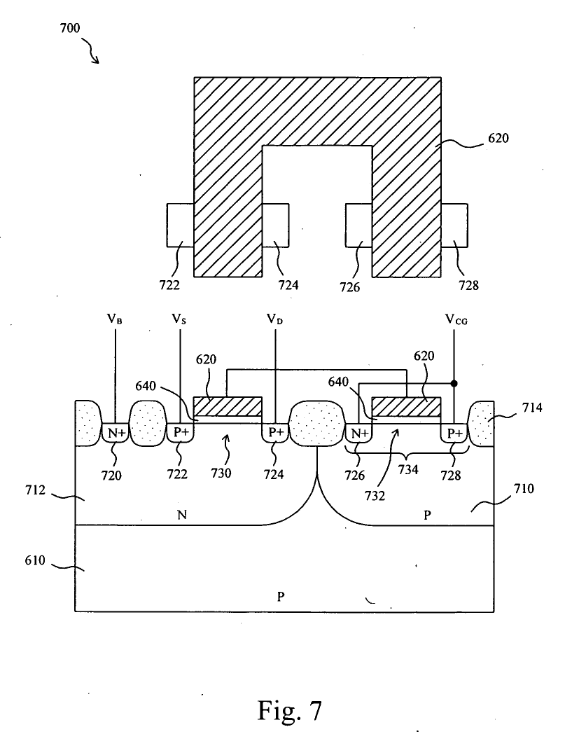

FIG. 7 provides a second embodiment according to the present invention. A non-volatile memory cell 700 comprises a substrate 610 which has a first conductive type, for example P-type, two wells 710 and 712 having opposite conductivity types, a pair of source 722 and drain 724 in the well 712, a channel 730 between the source 722 and drain 724, a control gate 734 in the well 710, a floating gate 620 extending from above the well 710 to above the channel 730, an insulation layer 640 between the floating gate 620 and the channel 730 and the well 710, and a region 720 which has N-type for serving as a well contact to prevent the well 712 from floating. The control gate 734 includes two regions 726 and 728 having opposite conductivity types, and a region 732 between the regions 726 and 728. In the cross-sectional view, the portions of the floating gate 620 above the channel 730 and the region 732 are separate, but in the top view, they are adjoined. In this embodiment, the insulation layer 640 includes a silicon dioxide, the floating gate 620 includes a polysilicon, and a field oxide layer 714 isolates the non-volatile memory cell 700 to be an independent unit, and the drain 722, region 726, and control gate 734. In other embodiments, a shallow trench isolation (STI) could take the place of the field oxide layer in this embodiment. When voltages V_{CG}, V_{D}, V_{S} and V_{B} are applied to the control gate 734, drain 724, source 722 and well contact 720, respectively, the voltage coupled from V_{CG} to the floating gate 620 induces the surface of the region 732 to invert from P-type to N-type. Since the induced N-type region is short to the region 726, the voltage at the surface of the region 732 is equal to V_{CG} which is the voltage applied to the control gate 734, and therefore no parasitic depletion capacitor would be induced in the coupling path of from V_{CG} to the floating gate 620, thereby achieving a higher coupling ratio. As a result, for programming the non-volatile memory cell 700, a lower voltage is required for V_{CG} to allow charges to enter into the floating gate 620 from the channel 730 through the insulation layer 640.

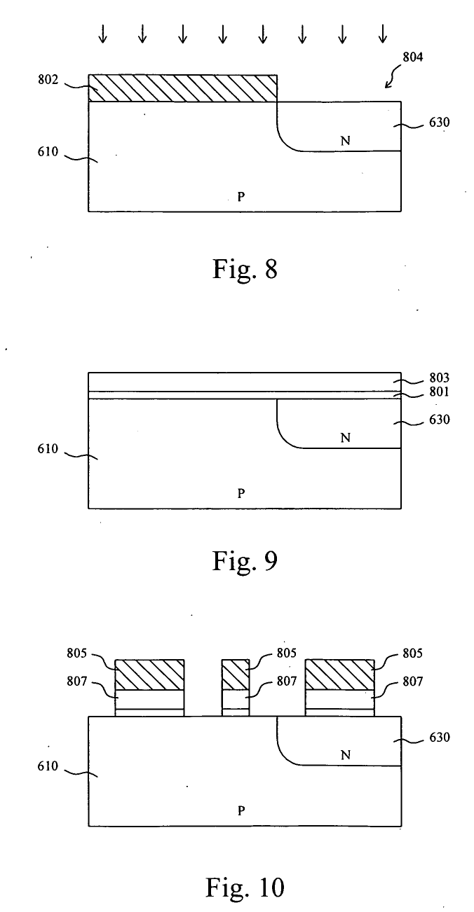

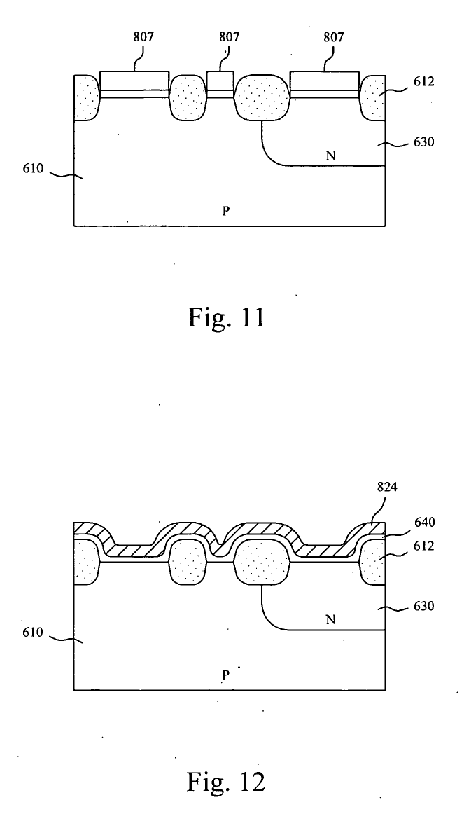

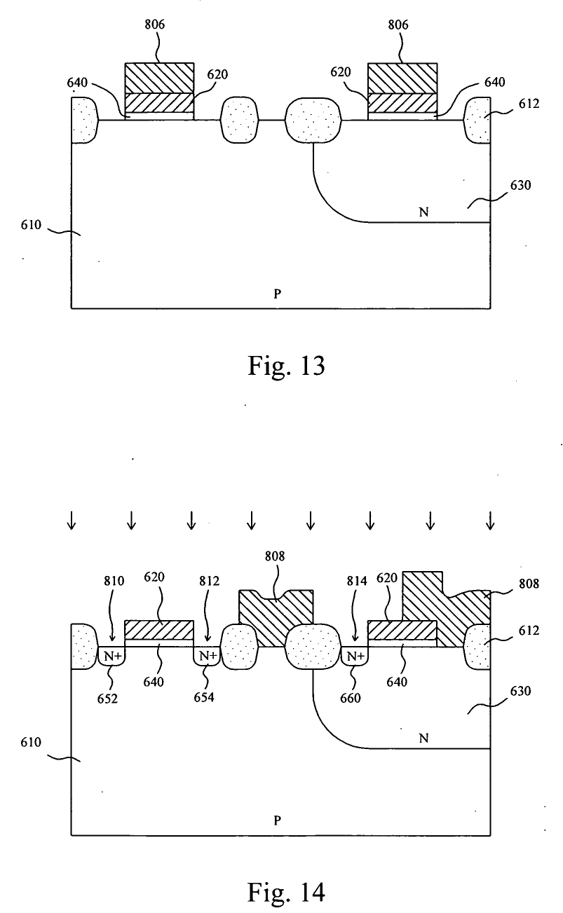

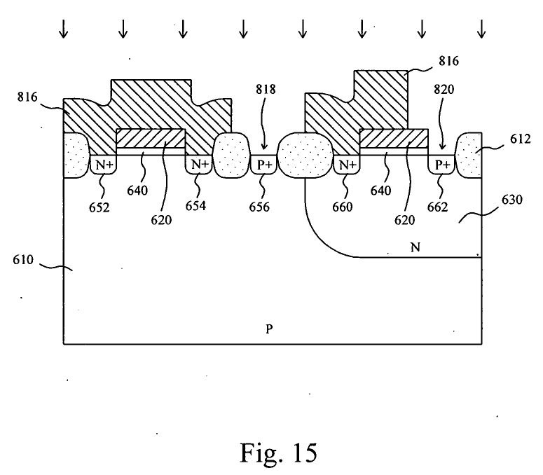

As shown by the structures of the above two embodiments, the non-volatile memory cell according to the present invention is fully logic process compatible and does not require extra steps or modifications in the manufacturing process. A process of making the non-volatile memory cell 600 is provided by FIGS. 8-15. As shown in FIG. 8, with a mask 802, the well 630 is formed through the exposed surface 804 of the P-type substrate 610 by for example an ion implantation of N-type dopants. Referring to FIG. 9, after the mask 802 is removed, a pad oxide layer 801 is grown and a nitride layer 803 is deposited. Then, as shown in FIG. 10, with a mask 805, the pad oxide layer 801 and nitride layer 803 are etched to form a hard mask 807 having three portions, two of them above the substrate 610 and the other above the well 630. After the mask 805 is removed, an oxidation process is performed with the hard mask 807 to form a field layer 612 on the exposed surface of the substrate 610, as shown in FIG. 11. Referring to FIG. 12, after removing the hard mask 807, an insulation layer 640 (for example silicon dioxide) and a conductive layer 824 (for example polysilicon) are formed in stack over the substrate 610. As shown in FIG. 13, the conductive layer 824 and insulation layer 640 are etched with a mask 806 to form the floating gate 620 above the substrate 610 and the well 630. Referring to FIG. 14, after removing the mask 806, with a mask 808, a self-aligned implantation is performed to form the source 652 on a surfaces 810 of the substrate 610, the drain 654 on a surface 812 of the substrate 610, and the highly-doped region 660 on a surface 814 of the well 630. Referring to FIG. 15, after removing the mask 808, with a mask 816, a self-aligned implantation is performed to form the highly-doped regions 656 and 662 on the surface 818 of the substrate 610 and the surface 820 of the well 630, respectively. Finally, the mask 816 is removed, and the non-volatile memory cell 600 shown in FIG. 6 is obtained. As shown in this embodiment, the region 660 is implanted concurrently with the step of forming the source 652 and drain 654 by the N-type implantation, and the region 662 is implanted concurrently with the step of forming the substrate contact 656 by the P-type implantation. Therefore, there is no need of extra steps or modifications in the process, and it is fully logic process compatible. In other embodiments, if STI is employed to take the role of the field oxide layer 612 in this embodiment, a STI process will be performed.

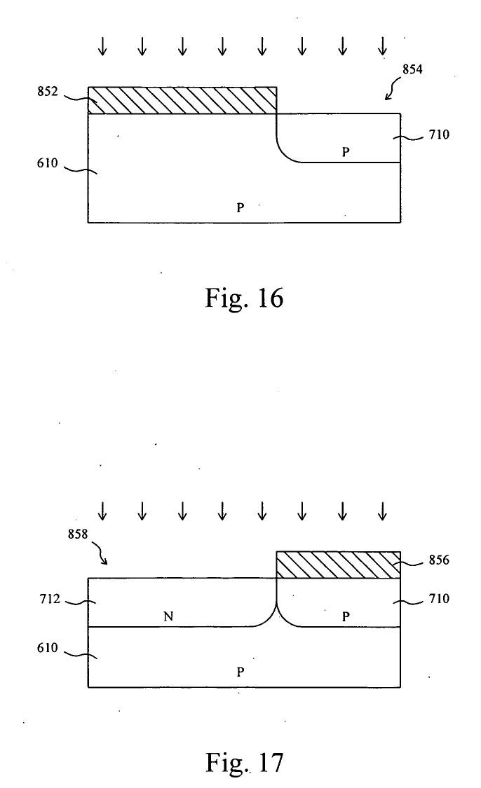

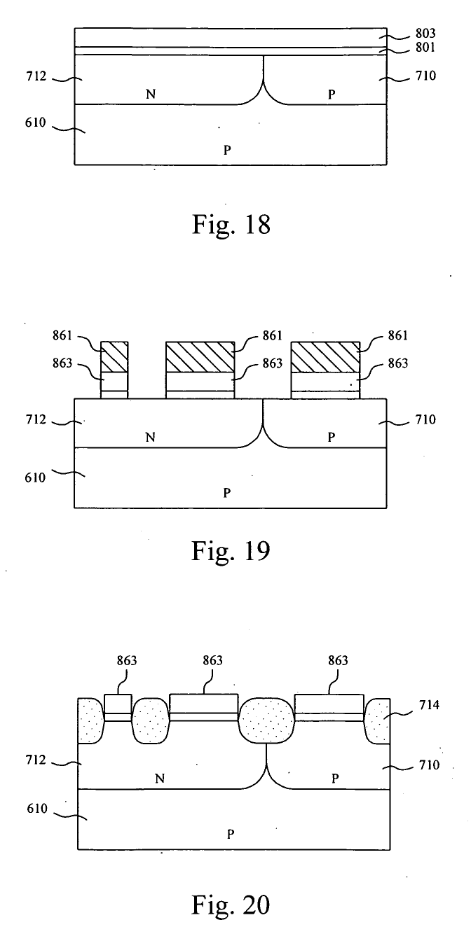

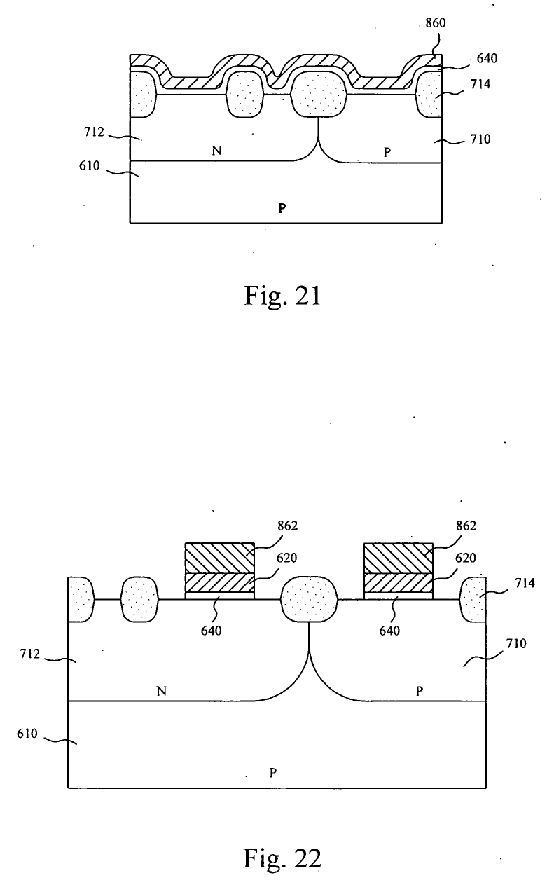

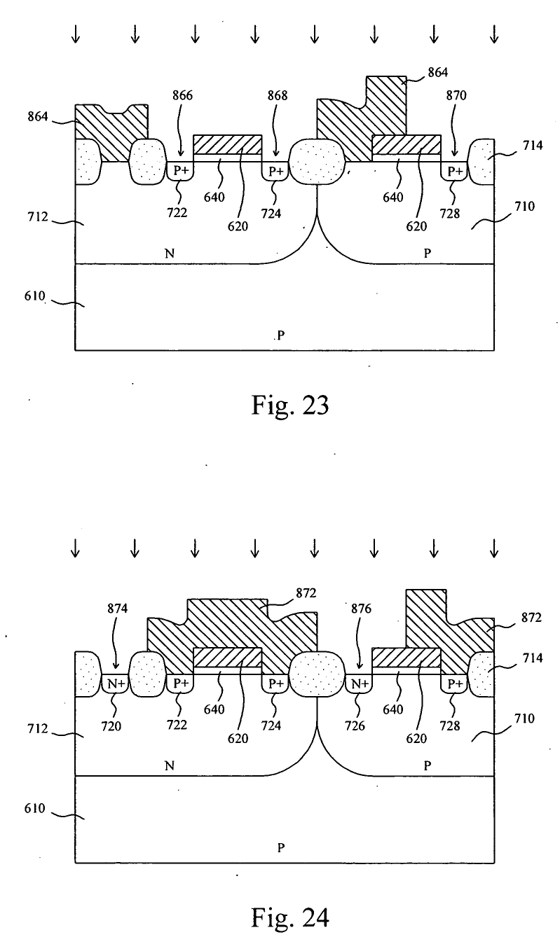

A process of making the non-volatile memory cell 700 is provided by FIGS. 16-24. As shown in FIG. 16, with a mask 852, the well 710 is formed through the exposed surface 854 of the P-type substrate 610 by for example an ion implantation of P-type dopants. Referring to FIG. 17, after the mask 852 is removed, with a mask 856, the well 712 is formed through the exposed surface 858 of the P-type substrate 610 by for example an ion implantation of N-type dopants. As shown in FIG. 18, after removing the mask 856, a pad oxide layer 801 is grown and a nitride layer 803 is deposited. Then, as shown in FIG. 19, with a mask 861, the pad oxide layer 801 and nitride layer 803 are etched to form a hard mask 863 having three portions, two of them above the well 712 and the other above the well 710. After the mask 861 is removed, an oxidation process is performed with the hard mask 863 to form a field oxide layer 714 on the exposed surface of the substrate 610, as shown in FIG. 20. Referring to FIG. 21, after removing the hard mask 863, an insulation layer 640 (for example silicon dioxide) and a conductive layer 860 (for example polysilicon) are formed in stack over the substrate 610. Referring to FIG. 22, the conductive layer 860 and insulation layer 640 are etched with a mask 862 to form the floating gate 620 above the wells 710 and 712. Referring to FIG. 23, after removing the mask 862, with a mask 864, a self-aligned implantation is performed to form the source 722 on a surface 866 of the well 712, a drain 724 on a surface 868 of the well 712, and the highly-doped region 728 on a surface 870 of the well 710. Referring to FIG. 24, after removing the mask 864, with a mask 872, a self-aligned implantation is performed to form a well contact 720 on a surface 874 of the well 712, and the highly doped region 726 on a surface 876 of the well 710. Finally, the mask 872 is removed, and the non-volatile memory cell 700 shown in FIG. 7 is obtained. As shown in this embodiment, the region 728 is formed concurrently with the step of forming the source 722 and drain 724 by the P-type implantation, and the region 726 is formed concurrently with the step of forming the well contact 720 by the N-type implantation. Therefore, there is no need of extra steps or modifications in the process, and it is fully logic process compatible. In other embodiments, if STI is employed to take the role of the field oxide layer 714 in this embodiment, a STI process will be performed.

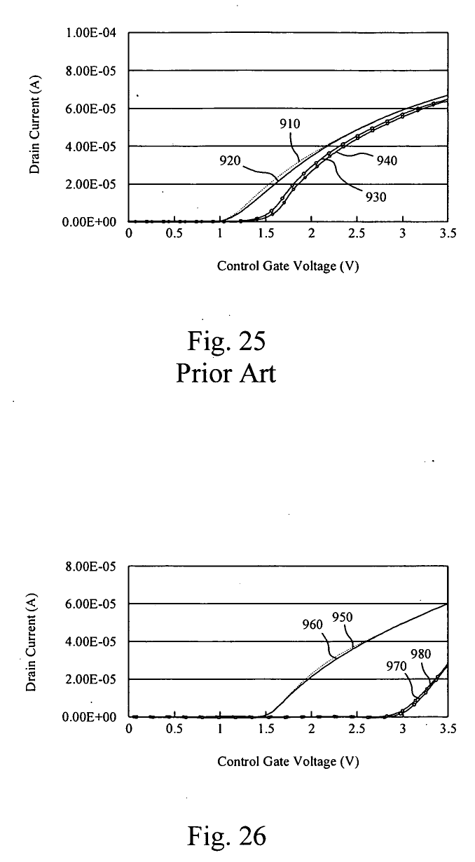

FIGS. 25 and 26 illustrate the I-V curves of the non-volatile memory cells 200 and 600 shown in FIGS. 2 and 6, respectively, in which curves 910 and 920 represent those of the conventional non-volatile memory cell 200 after initialization, curves 950 and 960 represent those of the non-volatile memory cell 600 according to the present invention after initialization, curves 930 and 940 represent those of the conventional non-volatile memory cell 200 after being programmed, and curves 970 and 980 represent those of the non-volatile memory cell 600 according to the present invention after being programmed. Under identical operational conditions, for example being programmed with 8.5 V for 30 ms, in comparison with the curves of the conventional non-volatile memory cell 200, the curves of the non-volatile memory cell 600 according to the present invention after initialization and being programmed are significantly different at lower voltages, for example 2 V, indicating that the non-volatile memory cell 600 according to the present invention is capable of being programmed with low voltages, for example 8.5 V, namely a higher coupling ratio is obtained.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A process of making a non-volatile memory cell, comprising the steps of:
forming a well on a substrate, the substrate having a first conductivity type, and the well having a second conductivity type opposite to the first conductivity type;
forming a floating gate having a first portion above the substrate and a second portion above the well; and
forming a pair of source and drain outside the well, and a first region having the first conductivity type and a second region having the second conductivity type in the well;
wherein a third region between the first and second regions is under the first portion of the floating gate.

2. The process of claim 1, wherein the pair of source and drain and the second region are formed by a same ion implantation.

3. A process of making a non-volatile memory cell, comprising the steps of:
forming two wells on a substrate, the substrate and first well having a first conductivity type, and the second well having a second conductivity type opposite to the first conductivity type;
forming a floating gate having a first portion above the first well and a second portion above the second well; and
forming a pair of source and drain in the second well, and a first region having the first conductivity type and a second region having the second conductivity type in the first well;
wherein a third region between the first and second regions is under the first portion of the floating gate.

4. The process of claim 3, wherein the pair of source and drain and the first region are formed by a same ion implantation.
